(19) United States
(12) Patent Application Publication
(10) Pub. No.: US 2009/0065242 A1
(43) Pub. Date: Mar. 12, 2009

(54) MANUFACTURING METHOD OF PRINTED WIRING BOARD AND PRINTED WIRING BOARD INCLUDING POTTING DAM OBTAINED BY USING MANUFACTURING METHOD

(75) Inventor: Masahiro SATO, Kanagawa (JP)

Correspondence Address: GREENBLUM & BERNSTEIN, P.L.C., 1950 ROLAND CLARKE PLACE, RESTON, VA, 20191, US

(73) Assignee: MULTI INC., Kanagawa (JP)

(21) Appl. No.: 12/127,112

(22) Filed: May 27, 2008

(30) Foreign Application Priority Data
May 28, 2007 (JP) 2007-140195

(51) Int. Cl. H05K 1/02; H05K 3/00

(52) U.S. Cl. 174/255; 29/846

(57) ABSTRACT

The present invention provides a manufacturing method of a printed wiring board including a potting dam of favorable shape and positional accuracy. The method includes a process A of preparing a substrate comprising a wiring pattern, a process B of providing a resin layer on a surface of the substrate comprising the wiring pattern, a process C of fluidizing the resin layer by heating and deforming the resin layer to obtain a potting dam shape using a press plate comprising a mold shape, and a process D of removing the press plate comprising a mold shape to expose the resin layer comprising a portion with the deformed potting dam shape. When required, a process E of removing unnecessary portions of the resin layer deformed to obtain the potting dam shape can be added after the process D.

### BACKGROUND OF THE INVENTION

1. Field of the Invention

The present invention relates to a manufacturing method of a printed wiring board and a printed wiring board including a potting dam obtained by using the manufacturing method.

2. Description of the Related Art

In the manufacturing of integrated circuit with resin encapsulation and substrate units mounted with passive devices and/or active devices on a printed wiring board, resin encapsulation is usually performed to protect the devices. When a resin with a high viscosity is used for encapsulation, the area required for the resin encapsulation is small, but the resin after finishing encapsulation may be thicker than required.

In contrast, when a resin for encapsulation with a low viscosity is used, the height of the resin after finishing encapsulation can be suppressed, but the resin tends to spread excessively. Hence, when the low-viscosity resin for encapsulation is used, potting dams to prevent the resin for encapsulation from flowing out of the resin encapsulation area are formed at peripheries of the resin encapsulation area by using a screen printing method and the like.

On this subject, Japanese Patent Application (Japanese Patent Laid-Open No. 2000-77440) points out the need to form dams to prevent the flow of a resin for encapsulation in a resin encapsulation process for a resin-encapsulated hybrid integrated circuit. However, the resin for encapsulation may sometimes flow out from the desired area by flowing over from top of above flow-preventing dams. To prevent such phenomenon, the application discloses use of a resin frame as the dam attached on a circuit board to surround areas where semiconductor chips and bonding wires are arranged. By dispensing the resin for encapsulation into the resin frame, the resin for encapsulation is reliably prevented from flowing out of the area of the resin frame. After curing the resin for encapsulation, the resin frame is removed.

In the example of the Japanese Patent Laid-Open No. 2000-77440, a method is disclosed by which resin frames formed using a resin with a high releasability, or metal frames made of stainless steel or the like, are separately attached in each portion of semiconductor chip with bonding wire on the wiring board. A thermosetting resin for encapsulation in liquid form is dispensed into the frames. After curing the resin for encapsulation, the frames are removed. Thus, in the method disclosed in Japanese Patent Laid-Open No. 2000-77440, accurate positioning for resin-encapsulated portion is required for the frames which function as the potting dams, releasability of the frames against to the resin for encapsulation, and management of contact between the frames and the substrate.

An another Japanese Patent Application (Japanese Patent Laid-Open No. 2006-100489), discloses a method for providing a printed wiring boards and electronic devices capable of preventing potting resin from flowing out of encapsulation area. A printed wiring board is formed to include a conductor pattern formed on an upper surface of an insulating substrate, electrodes portion for mounting parts formed for electrically connecting the conductor pattern with mounted electronic devices, and band-shape resin-flow preventing dams formed at peripheries of resin encapsulation areas that include the areas for mounting the electronic devices. Resin-flow preventing dams have external side-walls against to the resin encapsulation portions which intersect with the upper surface at an acute angle.

In the example of Japanese Patent Laid-Open No. 2006-100489, the external side-walls of the dam against to the resin encapsulation area intersect with the upper surface at an acute angle, and so the dams have a cross-sectional profile which substantially resembles an inverted trapezoid. Hence, when the potting resin is poured into the encapsulation area, there is significant swelling above the dam due to the effects of surface tension. This allows potting resin height to be secured with a low dam. Thus, construction method of the potting dam disclosed in Japanese Patent Laid-Open No. 2006-100489 requires the potting dam to have an inverted trapezoidal profile in cross-section.

In the method disclosed in the Japanese Patent Laid-Open No. 2000-77440, when the wiring board is a ceramic substrate or the like, the flatness and smoothness may be favorable and the accurate contact between the frame and the substrate can be assured by the accurate frame processing. However, in the case of an organic substrate, there is a surface unevenness of around 1 micron-meter caused by a glass cloth. Moreover, substrates may have warp and/or twist. Hence, the larger the frame, assurance of accurate contact between the frame and the substrate might be more difficult. When gaps exist between the frame and the substrate, it is obvious that resin leakage may occur. Also, the method is unsuitable for wide use and offers inferior productivity since careful handling is required for removing the frames without damaging the hybrid integrated circuit.

In the method disclosed in Japanese Patent Laid-Open No. 2006-100489, the dam formed on the surface of the insulating material has cross-sectional profile similar with an inverted trapezoid. And it requires use of over-etching by dry-etching with an etching mask pattern or over-exposure of a light sensitive material. Thus, the material constituting the potting dam in the process is processed under conditions which differ from preferred processing conditions. Generally speaking, it might be hard to stably obtain the desired shape under conditions which are far from preferred range of conditions to assure quality for materials used. Hence, even when identical process conditions are applied, deviations in the material may lead to excessive processing which narrows the area of the portion where substrate and the inverted-trapezoidal dam contact. Then separation at the contact portion may occur by the pressure of the poured resin for encapsulation. In contrast, if the processing is suppressed to reduce the risk of separation, the cross-sectional profile approaches to a rectangular shape, the resin for encapsulation may overflows from the dam, and the resin encapsulation effect is no longer obtained. To solve the above-described problem, the potting dam should be wider. However, when the potting dams are to be formed in the required portions, larger share for the potting dams in the areas of the printed wiring board is required. As a result, the range for resin encapsulation areas must be designed to be wider, and it may loose flexibility in the design of the printed wiring board.

To solve above described problems, a method in which a flexible dry film with suitable adhesion against to the organic substrate is used to form suitable potting dam with a height of few tens of micron-meter has been developed. However, to form potting dams with height exceeding 100 micron-meter, it is necessary to use a dry film of a corresponding thickness. However, even when parallel light is used to expose such a dry film, a reduction in the resolution of the dry film occur because of significant scattering at a position close to bonding surface where the film is bonded to the substrate. As a result, the formed potting dams cannot assure a suitable cross-sectional shape and positional accuracy.

### SUMMARY OF THE INVENTION

The present inventor thought out a manufacturing method of a printed wiring board including potting dams described below after diligent research to solve the above described problems. The manufacturing method is summarized to be composed of forming of a resin layer having potting dam shapes around the portion where encapsulation resin is potted; wirings for connection with external devices is exposed by removing the resin layer formed on the wirings, followed by resin encapsulation after mounting electronic devices at the exposed wirings.

The manufacturing method of the printed wiring board according to the present invention is manufacturing method of a printed wiring board including a potting dam, composed of:

a process A of preparing a substrate comprising a wiring pattern;

a process B of providing a resin layer on a surface of the substrate comprising the wiring pattern;

a process C of fluidizing the resin layer by heating, and deforming the resin layer to obtain a potting dam shape using a press plate comprising a mold shape;

a process D of removing the press plate comprising a mold shape to expose the resin layer comprising a portion deformed to the potting dam shape.

In the manufacturing method of the printed wiring board according to the present invention, the substrate of the process A may have a pad-shape wiring pattern for mounting an electronic device.

In manufacturing method of the printed wiring board according to the present invention, the resin layer of the process B may be formed from a semi-cured thermoplastic resin.

In the manufacturing method of the printed wiring board according to the present invention, the resin layer of the process B may be formed from a resin sheet made of a semi-cured thermoplastic resin.

In the manufacturing method of the printed wiring board according to the present invention, the resin layer of the process B may be formed from a resin sheet having a composite layer prepared by laminating a bonding sheet and a layer formed by using one selected from a thermoplastic resin and a semi-cured thermosetting resin.

In the manufacturing method of the printed wiring board according to the present invention, the resin sheet may be a resin sheet with openings which openings locate at a predetermined portion to form resin layer at just required area.

In the manufacturing method of the printed wiring board according to the present invention, the press plate comprising a mold shape used in the process C may be made of one selected from a metal plate and a ceramic plate including dimples for forming the potting dam shape.

In the manufacturing method of the printed wiring board according to the present invention, the press plate comprising a mold shape used in the process C may include, the dimples for forming the protruding potting dam shape are formed in one of a metal layer or a ceramic layer of a composite material prepared by bonding a plastic layer together with one of a ceramic layer and a metal layer.

In the manufacturing method of the printed wiring board according to the present invention, the dimples for forming the potting dam shape may be formed by processing chemical etching or physical etching.

In the manufacturing method of the printed wiring board according to the present invention, the press plate comprising a mold shape used in the process C may include a releasing layer on a surface thereof.

The manufacturing method of the printed wiring board according to the present invention may further include: a process E of obtaining the printed wiring board including the potting dam by removing an unnecessary portion of the resin layer while leaving necessary areas of the resin layer.

In the manufacturing method of the printed wiring board according to the present invention, the removal of the unnecessary portion of the resin layer in the process E may be performed by a chemical process on the unnecessary portion of the resin layer.

In the manufacturing method of the printed wiring board according to the present invention, the removal of the unnecessary portion of the resin layer in the process E may be performed by irradiating laser light on the unnecessary portion of the resin layer.

Printed wiring board according to the present invention: the printed wiring board according to the present invention is a printed wiring board including a potting dam obtained by using the above described manufacturing method of the printed wiring board.

The manufacturing method of the printed wiring board of the present invention which is composed of process A to process D and, if required, process E, makes it possible to stably manufacture a printed wiring board including potting dams which are formed at necessary portions with excellent shape and positional accuracy. The press plate comprising a mold shape used in the above-mentioned process can be prepared by using one-sided printed wiring board manufacturing methods. Thus, it is possible to manufacture the printed wiring board including the potting dams by applying manufacturing processes used in manufacturing of the conventional printed wiring boards, and no special processing conditions are required. Hence, stable quality is assured in the manufactured printed wiring boards including potting dams. Also, when the substrate with electronic devices mounted thereon is separated to assemble onto another substrate, the potting dam shapes can be used as guides for position-matching. The guide shape can also be designed separately against to the potting dam.

### BRIEF DESCRIPTION OF THE DRAWINGS

FIG. 1 is a cross-sectional schematic view illustrating concepts of the processes A to E according to the present invention;

FIG. 2 is a schematic view showing an example of an etching resist pattern used when processing to form dimples in a press plate comprising a mold shape;

FIG. 3 is a cross-sectional view of the press plate comprising a mold shape on which chemical polishing has been performed;

FIG. 4 is a top view of the press plate comprising a mold shape on which chemical polishing has been performed;

FIG. 5 is a cross-sectional view of the press plate comprising a mold shape on which chemical etching has been performed;

FIG. 6 is a top view of the press plate comprising a mold shape on which chemical etching has been performed;

FIG. 7 is a cross-sectional view of the printed wiring board obtained by using the press plate comprising a mold shape on which chemical polishing has been performed;

FIG. 8 is a top view of the printed wiring board obtained by using the press plate comprising a mold shape on which chemical polishing has been performed;

FIG. 9 is a cross-sectional view of the printed wiring board obtained by using the press plate comprising a mold shape on which chemical etching has been performed; and

FIG. 10 is a top view of the printed wiring board obtained by using the press plate comprising a mold shape on which chemical etching has been performed.

### DETAILED DESCRIPTION OF THE PREFERRED EMBODIMENTS

The manufacturing method of the printed wiring board according to the present invention:

The manufacturing method of the printed wiring board according to the present invention is manufacturing method of a printed wiring board including a potting dam, comprising:

a process A of preparing a substrate comprising a wiring pattern;

a process B of providing a resin layer on a surface of the substrate comprising the wiring pattern;

a process C of fluidizing the resin layer by heating, and deforming the resin layer to obtain a potting dam shape using a press plate comprising a mold shape; and

a process D of removing the press plate comprising a mold shape to expose the resin layer comprising a portion deformed to be potting dam shape.

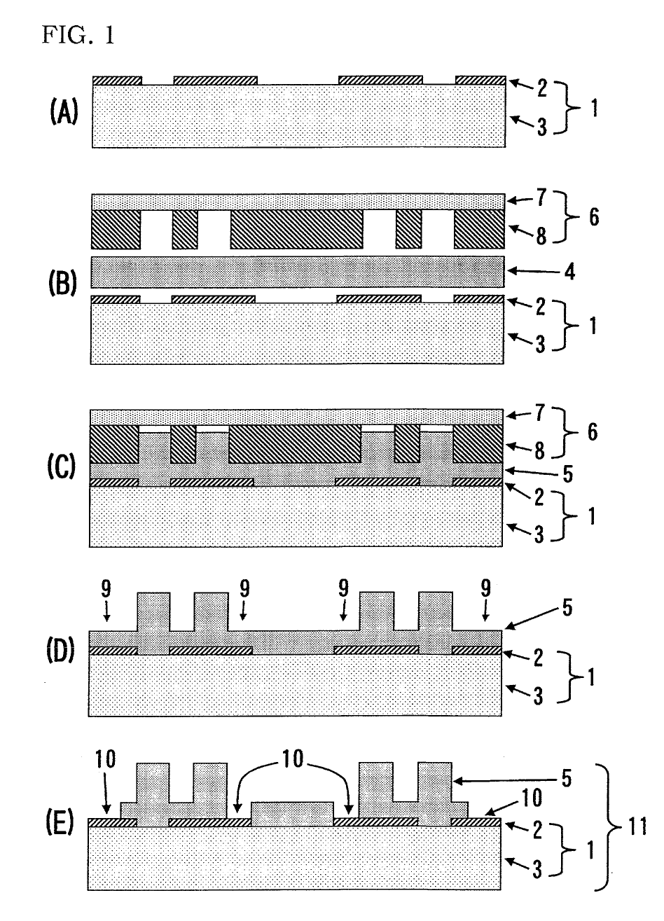

The process steps will be described with referring to FIG. 1.

The process A is a process for preparing the substrate comprising the wiring pattern. The process A makes use of a substrate 1 having construction in which a wiring pattern 2 is formed on an insulating resin substrate 3 as shown in FIG. 1A. As described above, electronic devices comprising active devices such as IC chips, LED devices and the like and passive devices such as MLCC, resistors and the like are mounted on a printed wiring board 11, shown in FIG. 1E, which includes potting dams 5 obtained by processing the prepared substrate 1. Resin encapsulation is then performed on the portions in the printed wiring board. Hence, the substrate 1 prepared in the process A includes a pad-shape wiring pattern 2 for mounting electronic devices and the like.

The process B is a process for providing a resin layer on the surface of the substrate 1 which includes the wiring pattern 2. FIG. 1B shows an example construction in which a resin sheet 4 is laid on the substrate 1, and a press plate comprising a mold shape 6 in which dimples 8 are formed to exposes a plastic layer 7 is arranged on the resin sheet 4 where the dimples 8 contact to the resin sheet 4. In FIG. 1B, the resin sheet 4 is used as the resin layer, but the resin layer is not limited to be a sheet form. The resin layer may also be formed by applying a thermosetting resin varnish to the surface of the substrate 1 comprising the wiring pattern 2, followed by drying and heating the resin to be a semi-cured state. The resin type is not limited also. Any resin which has resistance against to both the solvent contained in the resin varnish for encapsulation and thermal deformation in the thermal processing applied to cure the resin for encapsulation after forming the potting dam shape by heat molding may be used.

In the manufacturing method of the printed wiring board according to the present invention, the resin layer of the process B may be formed by a semi-cured thermosetting resin. When a thermosetting resin is used, the resin varnish can be applied to the surface of the substrate 1 comprising the wiring pattern 2 followed by drying and heating the resin to be a semi-cured state in the manner described above. In addition, it may also be available to apply the resin varnish so as to fill the dimples 8 in the press plate comprising a mold shape 6, followed by semi-cure the resin varnish, and then the resin is used in the semi-cured state. Further, as the thermosetting resins have excellent fluidity when heated, it may make it easy to form potting dams of an anticipated shape.

The material most preferably used as the thermosetting resin is epoxy resin which has been used successfully in a broad range of the printed wiring board applications. In particular, when the substrate 1 is composed of epoxy resin, mostly preferred epoxy resins to be selected are the same type. This is because selecting an epoxy resin of the same type makes it possible to obtain a printed wiring board with well-balanced in adhesion, heat resistance, cost and the like through the experiences in the field of multi-layer printed wiring board manufacturing. The epoxy resins used may be a blended resin prepared by selecting from Novolac epoxy resin, bisphenol A-type epoxy resin, bisphenol F-type epoxy resin, bisphenol S-type epoxy resin and the like. In addition, a hardener such as an amine hardener, an acid anhydride hardener, a phenol hardener, a Lewis acid or salt thereof, or a dicyandiamide and a curing accelerator such as an Imidazole compound, a triamine compound, or a triphenyl-phosphine compound can be used if required.

In the manufacturing method of the printed wiring board according to the present invention, the resin layer 5 of the process B can also be formed by using resin sheet 4 which is made of a semi-cured thermosetting resin. The resin sheet 4 can be prepared by applying the above-described resin varnish on a release film or the like with a predetermined thickness, followed by drying, heating, and peeling off the finished semi-cured resin sheet from the release film. Moreover, a semi-cured resin sheet formed by impregnating a glass cloth or the like with a thermosetting resin is easy in handling and applicable with many kind of processing. The resin sheet 4 used here may also be a prepreg (such as R1661 manufactured by Matsushita Electric Works, Ltd.) or a resin sheet (such as AD7006 manufactured by Risho Kogyo Co., Ltd.). So, it is preferable to select from products able to purchase in the market, because such resin sheets have the advantages of being convenient and having stable properties.

In the manufacturing method of the printed wiring board according to the present invention, the resin layer of the process B may alternatively be formed using a resin sheet 4 which is a resin sheet having a composite layer composed of bonding sheet and a layer formed by using one selected from a thermoplastic resin and a semi-cured thermosetting resin. As described above, when a thermosetting resin is used, the thermosetting resin is preferably combined with a resin of the same type. When combination of a resin of a different type is applied, it may result inferior adhesion and/or heat resistance. When the thermosetting resin is combined with a resin of a different type, it is effective to use a bonding sheet to obtain a favorable adhesion between the substrate and the potting dams. When a thermoplastic resin is used, the heat resistance of the substrate is insufficient because the thermoplastic resin must be elevated its temperature of approximately 300-deg. C. to achieve the adhesion required. However, a bonding sheet may help to obtain adhesion and allow a process performed at a temperature marginally exceeding the softening point of the thermoplastic resin. The bonding sheet can be formed by using the above-described epoxy resin or the like. Particularly, a varnish which has been blended to perform adhesion between the substrate resin and the thin varnish layer is coated on a release film, followed by separating the semi-cured sheet from the release film after curing. When the bonding sheet is too thin and difficult to handle, the bonding sheet with the release film may be adjusted to certain shape, provisionally bonding the bonding sheet to the surface to be bonded, and then the release film is peeled off. Alternatively, a commercially available bonding sheet can be selected.

In the manufacturing method of the printed wiring board according to the present invention, the resin sheet can be a resin sheet with openings which openings locate at a predetermined portion to enable formation of resin layer at just required are. When devices are mounted on the printed wiring board by wire bonding, the terminal portions are gathered in mounting areas. Under such an arrangement, the wire bonding terminal portions and mounted devices are encapsulated with resin at once. Hence, when potting dams are formed on the printed wiring board, the openings are formed in the resin encapsulation areas, and the press plate comprising a mold shape 6 which forms potting dams surrounding the openings is used. Since there is no need for a subsequent process to remove the resin layer from the terminal portions, productivity is improved, and the waste products generated through a resin removal process are reduced. However, even when the resin sheet with openings is used, a resin layer may sometimes be formed on the terminal portions. In such cases, a subsequent process to remove the resin layer from the terminal portions is required. In addition, when the resin sheet with openings is used, a position matching guide may help to improve accuracy in the position matching among the substrate 1, the resin sheet 4 and the press plate comprising a mold shape 6 when obtaining the construction of FIG. 1B.

In the process C, the resin layer is fluidized by heating, and deformed to obtain the potting dam shape in the resin layer 5 using the press plate comprising a mold shape 6. FIG. 1C shows the resin layer 5 in a fluidized state which is filling the dimples 8 of the press plate comprising a mold shape 6 in a process going to finish the potting dam shape. Thus, when the press plate comprising a mold shape 6 formed with the dimples 8 on the surface is used, the resin layer 5 fluidized by heating is deformed according to the shape of the dimples 8. After finishing by cooling, the resin layer 5 that includes the potting dam shapes is obtained. It should be noted that when a thermoplastic resin is used in the process, the potting dam shape is formed by plastic deformation rather than fluidization.

A hot press used in conventional printed wiring board manufacturing process may be applicable to the heating apparatus used in the process C. The specific heating conditions may vary depending on the components of the resin layer. However, when the epoxy resin similar with the prepreg used in printed wiring board manufacturing is applied, it can be performed by the process conditions which are approximately the same with a press cycle when multi-layer printed wiring boards are manufactured by using the prepreg.

In the manufacturing method of the printed wiring board according to the present invention, the press plate comprising a mold shape 6 used in process C is preferably a metal plate or a ceramic plate comprising the dimples 8 for forming the potting dam shapes. The press plate comprising a mold shape 6 used in the process should be used repeatedly for manufacturing printed wiring boards of the same design. Hence, it is preferable to use a metal plate or ceramic plate which does not deform under heat cycle for deformation of the resin layer.

When a metal plate is used, the plate is not limited to be composed of one metal, and a clad plate formed by bonding a plurality of metal layers together is also available. When the metal plate composed of one metal is used for a hot pressing method, a stainless steel hardly show problems because many experiences as a press plate are adopted in such applications. Alternatively, aluminum or copper may be used. Since the heat conductivities of both aluminum and copper are better than that of stainless steel, such materials make it easier to obtain potting dam of the desired shape. When a clad plate prepared by bonding metal layers together is used, it is available to select any of a number of popular materials comprising copper with aluminum, copper with nickel, and copper with tin.

Ceramic plates are manufactured by a sintering method and a favorable shape may be obtained more easily, but has drawback in flexibility. Hence, when a ceramic plate is used in the hot press method, crack may be caused by unevenness in the substrate surface, so it is preferable to choose a cermet or a zirconia ceramic having an excellent toughness in the ceramic plate.

In the manufacturing method of the printed wiring board according to the present invention, the dimples 8 formed on the press plate comprising a mold shape 6 used in the process C for forming the protruding potting dam shape are formed in one of a metal layer or a ceramic layer of a composite material prepared by bonding a plastic layer 7 together with one of a ceramic layer and a metal layer. If the metal layer or the ceramic layer comprising the composite material has a uniform thickness, dimples 8 having a uniform depth can be formed by performing the process to expose the plastic layer 7 at bottom portions of the dimples 8 formed in the metal layer or the ceramic layer.

When a copper clad laminate, which is a popular base material available in the market, is used as the composite material, particular advantages in terms of delivery and cost might be achieved. The grade and thickness of the copper layers of the copper clad laminate to be selected can be easily determined by the mold temperature for the resin layer to be the potting dams and the height of the dams to be formed. When an FR-4 prepreg is used as the resin layer and the potting dam height is to be 100 mm, an FR-5 copper clad laminate with a copper foil thickness of 100 mm can be used.

In the manufacturing method of the printed wiring board according to the present invention, the dimples 8 which form the potting dam shapes are preferably formed by processing chemical etching or physical etching. The selection whichever the chemical etching and the physical etching is made after considering the properties of materials forming metal layer or ceramic layer in which the dimples 8 are to be formed.

The chemical etching is appropriate when the dimples 8 are formed to expose the plastic layer 7 in the composite material made up of the metal or ceramic layer and the plastic layer 7. Strong alkalis may be used for processing the ceramic materials such as alumina and the like. However, chemical etching is particularly suitable for forming the dimples 8 in a metal layer. When the metal layer is copper, it is possible to employ fine pattern forming technologies which have been developed for the manufacturing of printed wiring boards. Above technologies including resist forming, optimized compositions of etching solution and apparatuses, optimized crystal structure in the copper to be etched and the like. Further, the exposing, developing and etching apparatuses used in the manufacturing of conventional printed wiring boards can be applied, and it means that comparatively large printed wiring boards can be handled. Thus, such methods are preferable in terms of both productivity and cost.

When the above-described clad plate formed by bonding the metal layers together is used, selective etching can be performed among the chemical etching. Hence, it is easy to control the etching depth and the height of the potting dams also. When the metal layers are composed of aluminum and copper, just aluminium can be etched by sodium hydroxide solution or hydrochloric acid. In contrast, just copper can be etched by an aqueous solution of sodium persulfate or an aqueous solution of ammonium persulfate.

Physical etching methods can be roughly divided into processing methods which make use of mechanical energy and processing methods which make use of heat energy. Of the methods which make use of mechanical energy, the wet blast method offers a wide range of options for the dispersed polishing media and solution, and has an advantage in finishing the surface smooth. The methods which make use of heat energy, laser processing have an advantage to process minute areas. By selecting a laser wavelength that is optimum for the material to be processed, laser can be used for processing both metal layer and ceramic layer.

In the manufacturing method of the printed wiring board according to the present invention, the press plate comprising a mold shape 6 used in the process C may include a releasing layer on the surface. The resin layer used in the present invention may be an epoxy resin that is a thermosetting resin, since such resins are easily handled. By the way, the epoxy resins are good in adhesion.

When the epoxy resin is used, separation between the press plate comprising a mold shape 6 and the resin layer 5 having the potting dam shapes may become difficult according to the materials making up the mold shape of the press plate. In such cases, a highly heat resistant release agent such as silicon oil can be applied in advance to the surface of the dimples 8 of the press plate comprising a mold shape 6 to ease mold separation. Further, in the case when the widths of the formed potting dams are relatively larger than height, or a semi-circular cross-sectional profile of the potting dam is acceptable, a release film can be used as a mold-release layer.

The process D is for removing the press plate comprising a mold shape 6, and exposing the resin layer 5 which has been deformed to obtain the potting dam shape. The state shown in FIG. 1D is obtained after removing the press plate comprising a mold shape 6 to expose the resin layer 5 which has been deformed to obtain the potting dam shape. In the process, the press plate comprising a mold shape 6 is removed after cooling down to a temperature below the glass transition point in the case of the thermosetting resin and to a temperature below the softening point in the case of a thermoplastic resin.

The process E is carried out when required, and is a process for obtaining the printed wiring board including the potting dam 11 by removing an unnecessary portion of the resin layer while leaving necessary areas of the resin layer 5. Thus, the printed wiring board 11 which includes the potting dams shown in FIG. 1E is obtained. FIG. 1 shows an example in which portions 9 of the resin layer 5 which covers the wiring pattern 2 shown FIG. 1D are removed, and the printed wiring board 11 comprising the wiring pattern 2, the exposed portions 10 and the potting dams (the resin layer 5) shown in FIG. 1E is obtained.

According to the primally object of forming the potting dams, the resin layer portions which do not form the potting dams may all be removed, just leaving potting dams around the portions where resin is encapsulated on the terminals for connecting the electronic devices. However, in printed wiring boards, the portions where no electronic devices are connected are often covered with solder resist, permanent resist, or the like. Hence, to achieve function of a printed wiring board, in such wiring patterns, the terminal portions which connect to the electronic devices and the like should be exposed at least. Further, when the printed wiring boards which include via holes is manufactured, the resin layer at the via hole portions should be removed to allow via hole formation. Thus, the state of FIG. 1, in which no resin layer is formed at the portions where connection terminals are gathered and in the resin layers formed on the connection terminal in the other portions have been at least removed, is preferable in terms of both productivity and cost.

In the manufacturing method of the printed wiring board according to the present invention, the unnecessary portions 9 of the resin layer can be removed by using a chemical method in process E. When a chemical method is applied, it is preferable that the wiring patterns existing under the unnecessary portions 9 of the resin layer remain without damage. The chemical method can make use of a high-temperature, strongly alkaline solution comprising an oxidizing agent to remove the unnecessary portions 9 of the resin layer by oxidizing degradation and dissolution. Specifically, use of a commercially available desmear solution is preferable because the processing conditions are well-examined.

In the manufacturing method of the printed wiring board according to the present invention, the unnecessary portions 9 of the resin layer can also be removed by a laser irradiation in process E. The method for removing the unnecessary portions 9 of the resin layer by a laser irradiation is excellent in terms of processing speed. The method for removing the resin layer existing on the wiring pattern by a laser irradiation is a widely-used method in manufacturing of the multi-layer printed wiring boards by a build-up method, and the setting of the process conditions and the like are easy. However, carbon debris and the like are generally left on the wiring pattern surface after finishing the laser processing. Hence, the laser processing is generally combined with a chemical method such as desmearing treatment of the wiring pattern surface after the laser process. In manufacturing of the substrate 1 which is the material to be processed with above-described processing, methods for manufacturing printed wiring board are also applied. Thus, forming of a position determining pattern on the substrate may help to perform favorable positional accuracy for laser radiation to remove the resin layer.

The printed wiring board according to the present invention:

The printed wiring board of the present invention including potting dams is obtained by using the manufacturing method of the printed wiring board of the present invention. Thus, the printed wiring board on which potting dams they are formed by using the press plate comprising a mold shape comprising dimples is excellent in the shape and positional accuracy of the potting dams. As a result, it enables the resin encapsulation with a smaller amount of resin. Hence, the printed wiring board is excellent in cost performance. In addition, the method using the press plate comprising a mold shape on which the dimples have been formed by an etching method will be an answer applicable for miniaturization required in futures.

### EXAMPLES

In the example, a composite material was employed in the press plate comprising a mold shape used in the manufacturing of the printed wiring board including potting dams. The composite material as a starting material, FR-4 copper clad laminate having a board thickness of 2.0 mm comprising copper foil having a thickness of 200 micron-meter was used.

### Manufacturing of Mold-Attached Pressing Plate

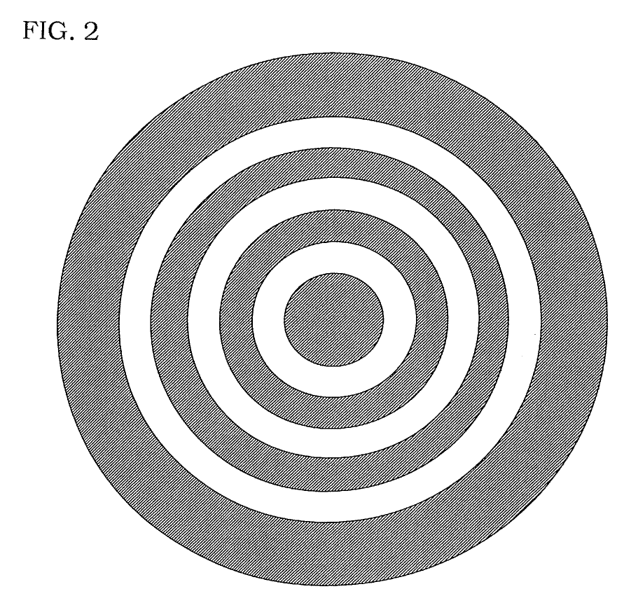

An etching method was applied in the process to form the dimples included in the press plate comprising a mold shape. Specifically, conventional printed wiring board manufacturing conditions using a dry film as an etching resist applied and copper (II) chloride solution as the etchant was applied. So, the descriptions in details for the process have therefore been omitted. FIG. 2 is a schematic top view of a negative developing pattern prepared for etching a copper foil corresponding to hatched portions. In FIG. 2, the inner diameter for the copper ring pattern formed in center is 1.0 mm and the outer diameter of the same is 2.0 mm. The inner diameter for the copper ring pattern of next center is 2.6 mm and the outer diameter of the same is 3.5 mm. The inner diameter for the copper ring pattern of outermost is 4.1 mm and the outer diameter of the same is 5.3 mm. In practice, the above described resist pattern so-called bull's eye patterns were patched independently in two columns, each column having nine with an interval of 20 mm lying on a straight line.

When the copper pattern obtained after etching was inspected after separation of the etching resist, burr-like materials were found on copper pattern edges corresponding to edges of the etching resist. Therefore, deburring process was performed to the edge after releasing of the etching resist. Two kind of deburring methods were applied to obtain two types of press plate comprising a mold shape. One of the methods was a chemical polishing by using a chemical mainly composed of sulfuric acid and hydrogen peroxide and another one was a chemical etching. The mold obtained is sometimes simply referred to as a “female mold”.

Cross-sections were investigated on the two types of press plate comprising a mold shape obtained in the manner described above to examine the finished states.

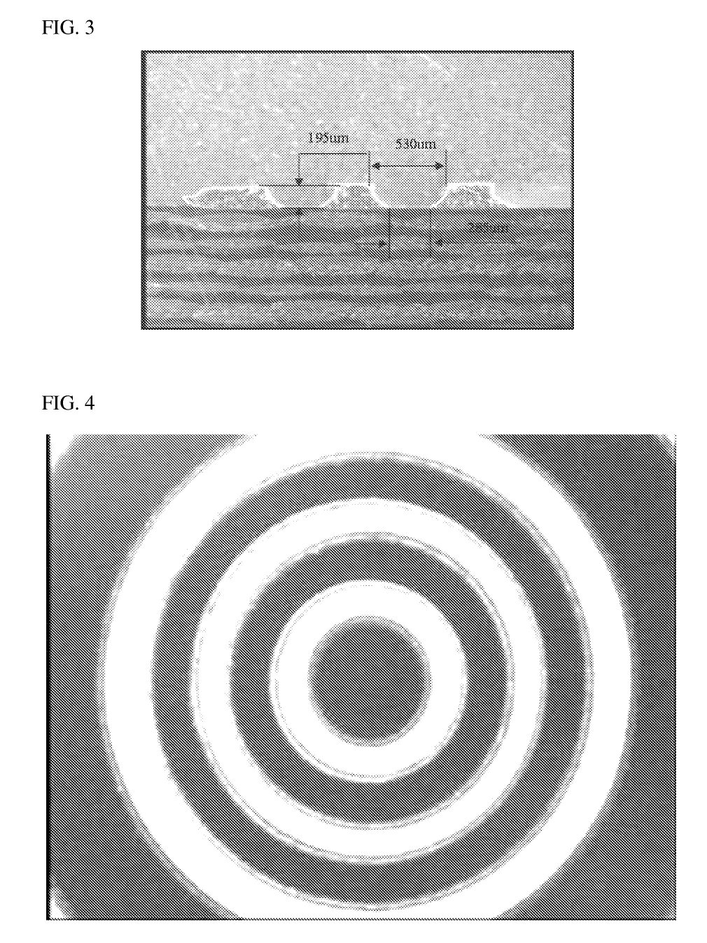

According to the investigations of the cross-section of the press plate comprising a mold shape on which the chemical etching was performed, the widths of the dimple ring of outermost from where the copper foil had been removed were 530 micron-meter at a top and 285 micron-meter at a bottom. The depth of the dimple ring was 195 micron-meter. The top view of the press plate comprising a mold shape after chemical polishing is shown in FIG. 4 and the cross-sectional view in FIG. 3.

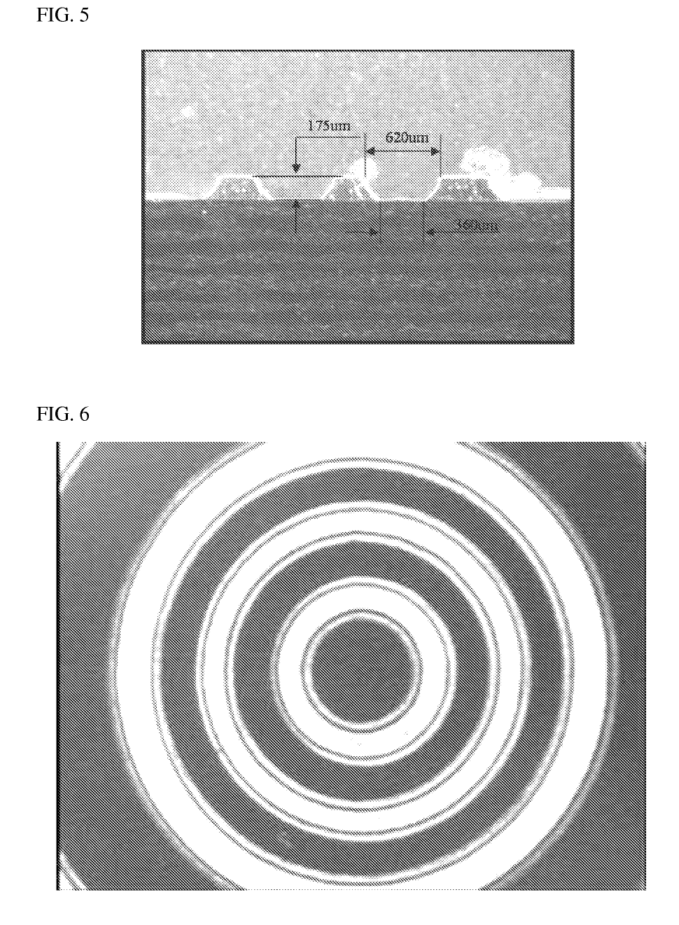

On the other hand, according to the observations of the cross-section of the press plate comprising a mold shape after chemical etching, the widths of the dimple ring of outermost where the copper foil has been removed were 620 micron-meter at a top and 360 micron-meter at a bottom. The depth of the dimple ring was 175 micron-meter. The top view of the press plate comprising a mold shape after chemical etching is shown in FIG. 6 and the cross-sectional view in FIG. 5.

### Manufacturing of the Printed Wiring Board Including Potting Dams

Printed wiring boards including potting dams were manufactured by carrying out process A to process D by using the two types of press plate comprising a mold shape manufactured in the manner described above.

In the process A, a 100 mm×200 mm rectangular substrate comprising two conductor-free slits was prepared. The substrate was manufactured by etching slit portions of copper foil from a copper clad laminate having a thickness of 0.1 mm bonded with 18 micron-meter electrodeposited copper foil. The prepreg R1661 having a thickness of 0.06 mm made by Matsushita Electric Works Ltd. was used as the resin layer of the process B.

A construction shown in FIG. 1B was performed by arranging the above-described materials where the bull's eye pattern included in the press plate comprising a mold shape had been aligned on the slits. The above construction was sandwiched between press plates made of stainless steel to form a book. The book was then kept in hot-press for 60 minutes between a hot plate with temperature of 180-deg. C. and pressure of 25 kgf/cm². After finishing the hot pressing, the cooled down book was took out from the hot press. The press plate comprising a mold shape was then removed to obtain the printed wiring board including the potting dam shown in FIG. 1D.

To examine the molding performance of the press plate comprising a mold shape, the cross-sectional view of the printed wiring board including the potting dams formed in the manner described above was investigated with the same magnification applied in the investigation on the cross-section of the press plate comprising a mold shape.

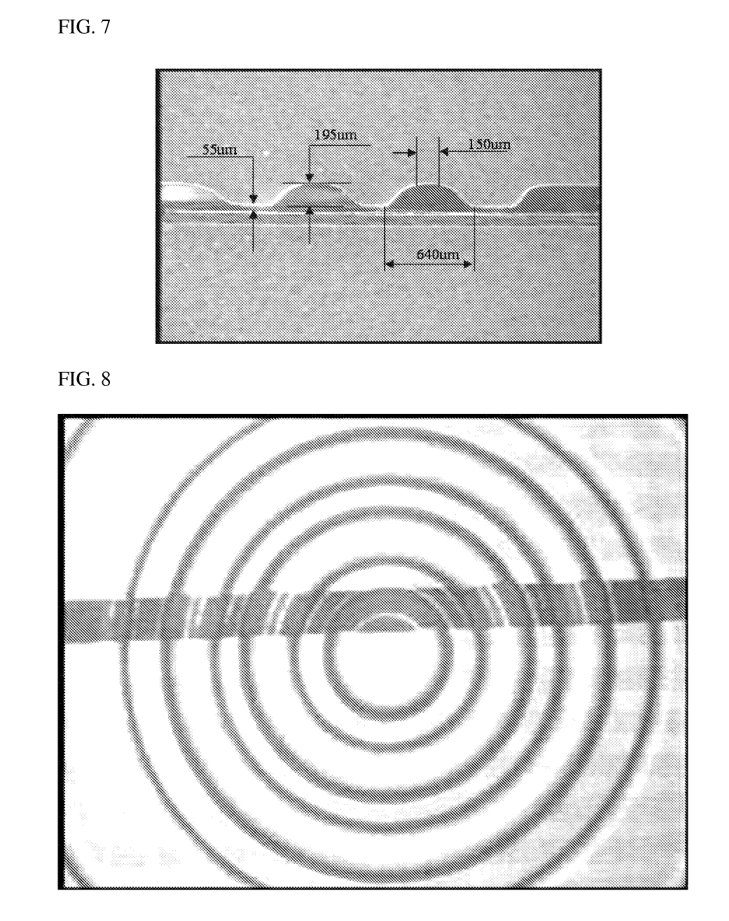

According to investigations of the cross-section of the printed wiring board including the potting dams obtained by using the press plate comprising a mold shape on which the chemical polishing was performed, the widths of the protruding ring of outermost were 150 micron-meter at a top and 640 micron-meter at a bottom. The height from the bottom resin layer surface to a top of the potting dams was 195 micron-meter and a thickness of the bottom resin layer was 55 micron-meter. The top view of the printed wiring board including potting dams obtained by using the press plate comprising a mold shape after chemical polishing is shown in FIG. 8 and the cross-sectional view in FIG. 7.

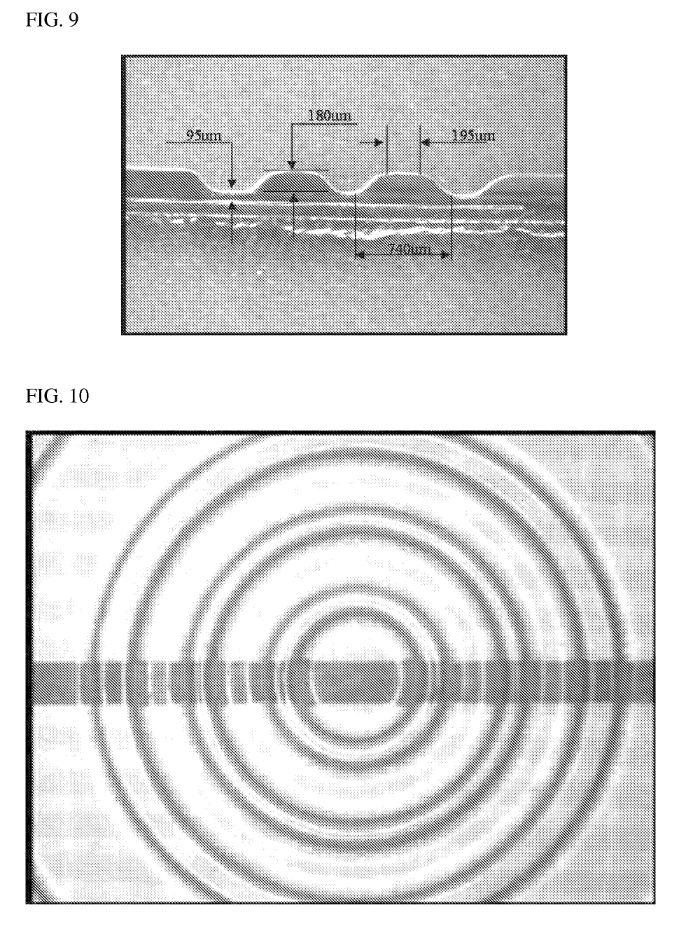

On the other hand, according to investigations of the cross-section of the printed wiring board including the potting dams obtained using the press plate comprising a mold shape after chemical etching, the widths of the protruding ring of outermost were 195 micron-meter at a top and 740 micron-meter at a bottom. The height from the bottom resin layer surface to a top of the potting dams was 180 micron-meter and a thickness of the bottom resin layer in the bottoms was micron-meter. The top view of the printed wiring board including potting dams obtained by using the press plate comprising a mold shape after chemical etching is shown in FIG. 10 and the cross-sectional view in FIG. 9.

### Comparison of the Potting Dam Shapes

In the examination of results shown above, relationship within shape of the dimples included in the press plate comprising a mold shape and shape of the potting dams were compared at corresponding locations. When the press plate comprising a mold shape was debarred by chemical polishing, a 530 micron-meter width at the top (a) of the dimple was made wider by 110 micron-meter to a 640 micron-meter width at the bottom (a) of the potting dam. A 285 micron-meter width at the bottom (b) of the dimple was made narrower by 135 micron-meter to a 150 micron-meter width of the top (b) of the potting dam.

When the press plate comprising a mold shape was debarred by chemical etching, a 620 micron-meter width at the top (a) of the dimple was made wider by 120 micron-meter to a 740 micron-meter width at the bottom (a) of the potting dam. A 360 micron-meter width at the bottom (b) of the dimple was made narrower by 165 micron-meter to a 195 micron-meter width at the top (b) of the potting dam. A summary of the above-described width and its change is given below in Table 1.

TABLE 1

| | Width (micron-meter) | | | | | |
|---|---|---|---|---|---|---|
| | Female mold | | Dam | | Change | |
| Deburring | Top | Bottom | Top | Bottom | (Mold to Dam) | |
| method | (a) | (b) | (b) | (a) | a | b |
| Chemical | 530 | 285 | 150 | 640 | 110 | −135 |
| polishing | | | | | | |
| Chemical | 620 | 360 | 195 | 740 | 120 | −165 |
| Etching | | | | | | |

As is clear in table 1, the tendencies seen in the finished potting dam shapes are common to the press plate comprising mold shapes of both deburring methods. The differences in size at corresponding positions are also of the same order. Hence, with manufacturing method of the printed wiring board including potting dams according to the present invention, it is easy to adjust shape of the dimples included in the press plate comprising a mold shape to give a desired shape of the potting dams.

According to the printed wiring board manufacturing method of the present invention which includes process A to process D and, if required, process E, it enables stable manufacturing of the printed wiring boards including potting dams with excellent accuracy in both shape and position required. The manufacturing method of printed wiring board of the present invention can be performed by applying similar process with the manufacturing process of the conventional printed wiring board. Hence, stable product quality is assured in the finished printed wiring boards which include the potting dams. Moreover, the area of the resin encapsulation portions formed on the printed wiring board including the potting dams is minimized. As a result, flexibility in the printed wiring board design might be broad. For example, the devices which require resin encapsulation can locate close to devices for which resin encapsulation is not required. Also, when the substrate with electronic devices mounted thereon is divided and to be assembled on another substrate, the potting dam shape can be used as a guide for position-matching. The guide shape can be designed separately to the potting dam.

What is claimed is:

1. A manufacturing method of a printed wiring board including a potting dam, comprising:
a process A of preparing a substrate comprising a wiring pattern;
a process B of providing a resin layer on a surface of the substrate comprising the wiring pattern;
a process C of fluidizing the resin layer by heating, and deforming the resin layer to obtain a potting dam shape using a press plate comprising a mold shape; and
a process D of removing the press plate comprising a mold shape to expose the resin layer comprising the portion deformed to be potting dam shape.

2. The manufacturing method of the printed wiring board according to claim 1, wherein
the substrate of the process A has a pad-shape wiring pattern for mounting an electronic device.

3. The manufacturing method of the printed wiring board according to claim 1, wherein
the resin layer of the process B is formed by a semi-cured thermosetting resin.

4. The manufacturing method of the printed wiring board according to claim 1, wherein
the resin layer of the process B is formed from a resin sheet made of a semi-cured thermosetting resin.

5. The manufacturing method of the printed wiring board according to claim 4, wherein
the resin sheet is a resin sheet with openings which openings locate at a predetermined portion to form resin layer at just required area.

6. The manufacturing method of the printed wiring board according to claim 1, wherein
the resin layer of the process B is formed from a resin sheet having a composite layer prepared by laminating a bonding sheet and a layer formed by using one selected from a thermoplastic resin and a semi-cured thermosetting resin.

7. The manufacturing method of the printed wiring board according to claim 6, wherein
the resin sheet is a resin sheet with openings which openings locate at a predetermined portion to form resin layer at just required area.

8. The manufacturing method of the printed wiring board according to claim 1, wherein
the press plate comprising a mold shape used in the process C is made of one selected from a metal plate and a ceramic plate including dimples for forming the potting dam shape.

9. The manufacturing method of the printed wiring board according to claim 8, wherein
the dimples for forming the potting dam shape are formed by processing chemical etching or physical etching.

10. The manufacturing method of the printed wiring board according to claim 1, wherein
the dimples formed on the press plate comprising a mold shape used in the process C for forming the protruding potting dam shape are formed in one of a metal layer or a ceramic layer of a composite material prepared by bonding a plastic layer together with one of a ceramic layer and a metal layer.

11. The manufacturing method of the printed wiring board according to claim 10, wherein
the dimples for forming the potting dam shape are formed by processing chemical etching or physical etching.

12. The manufacturing method of the printed wiring board according to claim 1, wherein
the press plate comprising a mold shape used in the process C includes a releasing layer on a surface thereof.

13. A manufacturing method of a printed wiring board according to claim 1, further comprising
a process E of obtaining the printed wiring board including the potting dam by removing an unnecessary portion of the resin layer while leaving necessary areas of the resin layer.

14. The manufacturing method of the printed wiring board according to claim 13, wherein
the removal of the unnecessary portion of the resin layer in the process E is performed by a chemical process on the unnecessary portion of the resin layer.

15. The manufacturing method of the printed wiring board according to claim 13, wherein the removal of the unnecessary portion of the resin layer in the process E is performed by irradiating the laser light on unnecessary portion of the resin layer.

16. A printed wiring board including a potting dam obtained by using the manufacturing method of the printed wiring board according to claim 1.

17. A printed wiring board including a potting dam obtained using the manufacturing method of the printed wiring board according to claim 13.
